(19) United States
(12) Patent Application Publication
(10) Pub. No.: US 2025/0096078 A1
(43) Pub. Date: Mar. 20, 2025

(54) SEMICONDUCTOR DEVICE AND METHOD OF MANUFACTURING THE SAME

(71) Applicant: Renesas Electronics Corporation, Tokyo (JP)

(72) Inventor: Hideaki TAMIMOTO, Tokyo (JP)

(21) Appl. No.: 18/808,400

(22) Filed: Aug. 19, 2024

(30) Foreign Application Priority Data
Sep. 19, 2023 (JP) 2023-150785

(51) Int. Cl. H01L 23/495; H01L 23/31

(52) U.S. Cl. CPC H01L 23/49513; H01L 23/3114; H01L 23/4952; H01L 23/49548

(57) ABSTRACT

A first surface of a die pad has: a first region; a second region that includes points respectively overlapping with four corners of a semiconductor chip; and a third region that is located around the second region. Also, a plurality of grooves is formed in the die pad at the second region. Also, each of the plurality of grooves terminates at a position not reaching each of the first region and the third region. Also, the plurality of grooves includes: a plurality of first grooves each extending in an extending direction of one of two diagonal lines of the semiconductor chip; and a plurality of second grooves each extending in an extending direction of another one of the two diagonal lines. Also, in each of the plurality of first grooves is arranged so as to intersect with one or more of the plurality of second grooves.

### CROSS-REFERENCE TO RELATED APPLICATIONS

The disclosure of Japanese Patent Application No. 2023-150785 filed on Sep. 19, 2023, including the specification, drawings and abstract is incorporated herein by reference in its entirety.

### BACKGROUND

The present invention relates to a semiconductor device and a method of manufacturing the same.

Here, there are disclosed techniques listed below.
[Patent Document 1]Japanese Unexamined Patent Application Publication No. 2004-335776
[Patent Document 2]PCT International Publication No. 2011-142006

In a semiconductor device where a semiconductor chip is mounted on a die pad and sealed with a sealing body, there is a case that a groove is formed in the die pad. For instance, Patent Document 1 discloses a semiconductor device in which a resin lock groove and a solder groove are provided in a frame on which a semiconductor pellet is mounted. Patent Document 2 discloses a semiconductor device in which a plurality of grooves is provided in a die pad on which a semiconductor chip is mounted.

### SUMMARY

One of the performance indicators required for the semiconductor device is reliability. The reliability of the semiconductor device refers to its ability to continue performing a function, which is predefined in a specification or the like, over a predetermined period. The semiconductor chip is, for example, fixed onto the die pad via a die bond material such as a solder material. From the perspective of improving the reliability of the semiconductor device, it is preferable that no delamination occurs between the die bond material and the die pad.

Other objects and novel features will become apparent from the description of this specification and the accompanying drawings.

A semiconductor device according to one embodiment includes: a die pad; and a semiconductor chip mounted on a first surface of the die pad. Here, the first surface of the die pad has: a first region that includes a point overlapping with a center of the semiconductor chip; a second region that is located around the first region and that includes points overlapping with the four corners, respectively; and a third region that is located around the second region. Also, a plurality of grooves is formed in the die pad at the second region. Also, each of the plurality of grooves terminates at a position not reaching each of the first region and the third region. Also, the plurality of grooves includes: a plurality of first grooves each extending in an extending direction of one of the two diagonal lines; and a plurality of second grooves each extending in an extending direction of another one of the two diagonal lines. Also, in each of the plurality of first grooves is arranged so as to intersect with one or more of the plurality of second grooves. Furthermore, each of the four sides of the semiconductor chip overlaps with one or more of the plurality of grooves.

According to one embodiment, the performance of the semiconductor device can be improved.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a transparent plan view showing an internal structure of the semiconductor device in a state that a sealing body shown in FIG. 1 is removed.

FIG. 4 is a cross-sectional view along a line A-A shown in FIG. 3.

FIG. 5 is an explanatory diagram schematically showing an example of a circuit provided in the semiconductor device shown in FIG. 1.

FIG. 6 is a cross-sectional view of a main portion showing an example of an element structure of a field-effect transistor shown in FIG. 5.

FIG. 7 is an enlarged plan view showing a die pad shown in FIG. 3.

FIG. 8 is an enlarged cross-sectional view of a part A shown in FIG. 4.

FIG. 9 is an enlarged plan view showing a modified example of the die pad shown in FIG. 7.

FIG. 10 is a flowchart showing an example of a manufacturing step for the semiconductor device shown in FIGS. 1 to 4.

FIG. 11 is an enlarged plan view showing a part of a lead frame prepared in a lead frame preparing step shown in FIG. 10.

FIG. 12 is a cross-sectional view showing a step of forming a groove shown in FIG. 8 by irradiating the die pad shown in FIG. 11 with a laser.

FIG. 13 is an enlarged plan view showing a state where a die bond material is applied onto one of the die pads shown in FIG. 11.

FIG. 14 is an enlarged plan view showing a state after the die bond material shown in FIG. 13 is pressed by a molding tool (spanker).

FIG. 15 is an enlarged cross-sectional view schematically showing a state where the die bond material shown in FIG. 13 is pressed by the molding tool (spanker).

FIG. 16 is an enlarged plan view showing a state where a semiconductor chip is mounted on the die bond material shown in FIG. 14.

### DETAILED DESCRIPTION

### Description of Forms, Basic Terms and Usage in this Application

In the present application, the description of embodiments is, as necessary, divided into a plurality of sections or the like for convenience, but unless expressly stated otherwise, these are not independent and separate from each other, regardless of the order of description, parts of a single example, one being a part of the detail or a part or all of a modified example of the other. Also, as a principle, descriptions of similar parts are omitted. Furthermore, each component in an embodiment is not essential, unless expressly stated otherwise, theoretically limited to that number, and obviously not so from the context.

Similarly, in the description of the embodiment and the like, “X consisting of A” or the like with respect to the material, composition, and the like does not exclude elements other than A, except when it is clearly indicated that this is not the case and when it is obvious from the context that this is not the case. For example, regarding a component, it means “X including A as a main component” or the like. For example, the term “silicon member” or the like is not limited to pure silicon, and it is needless to say that it also includes a member containing a SiGe (silicon-germanium) alloy, a multi-element alloy containing silicon as its main component, other additives, or the like. Also, when mentioning gold plating, Cu layers, nickel plating, etc., unless specifically stated otherwise, it includes not only pure substances but also members containing gold, Cu, nickel, etc., as their main components.

In addition, reference to a specific numerical value or quantity may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, hatching or dot patterns may be added to indicate that the region is not a void even if it is not a cross-section or to indicate the boundary of the area.

In the embodiments described below, as an example of semiconductor devices, semiconductor devices referred to as power devices, or power semiconductor devices, which are incorporated into power control circuits such as power supply circuits, are discussed. The semiconductor devices described below are incorporated into power conversion circuits and function as switching elements.

### <Semiconductor Device>

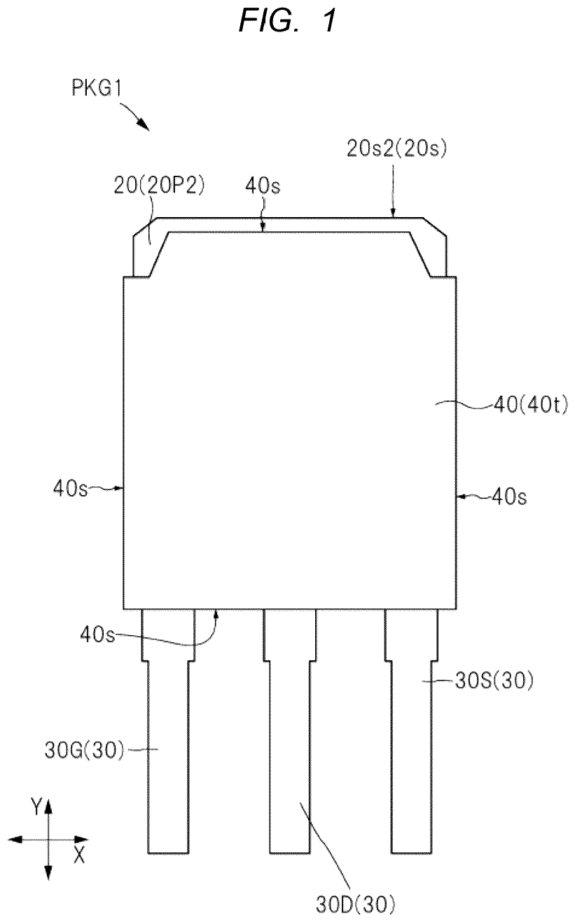

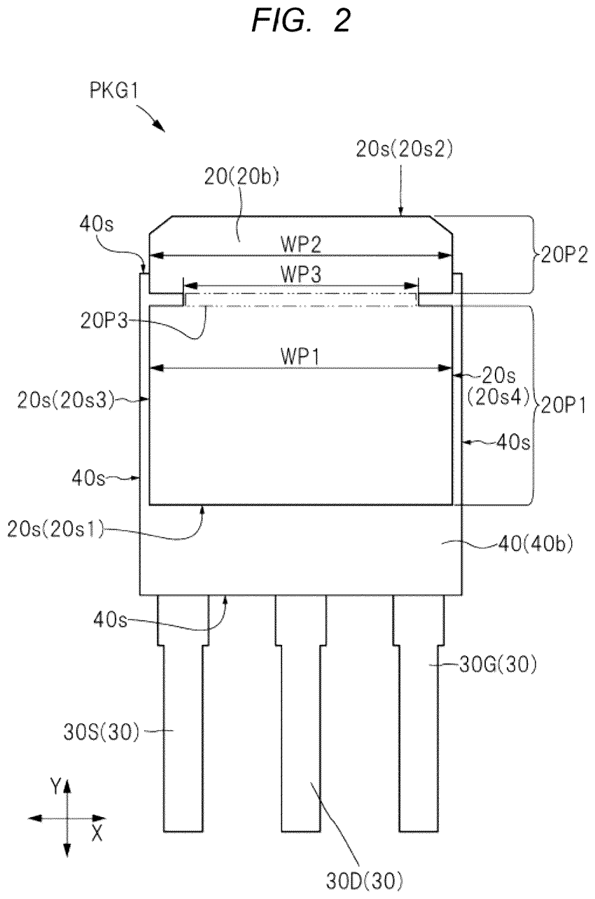

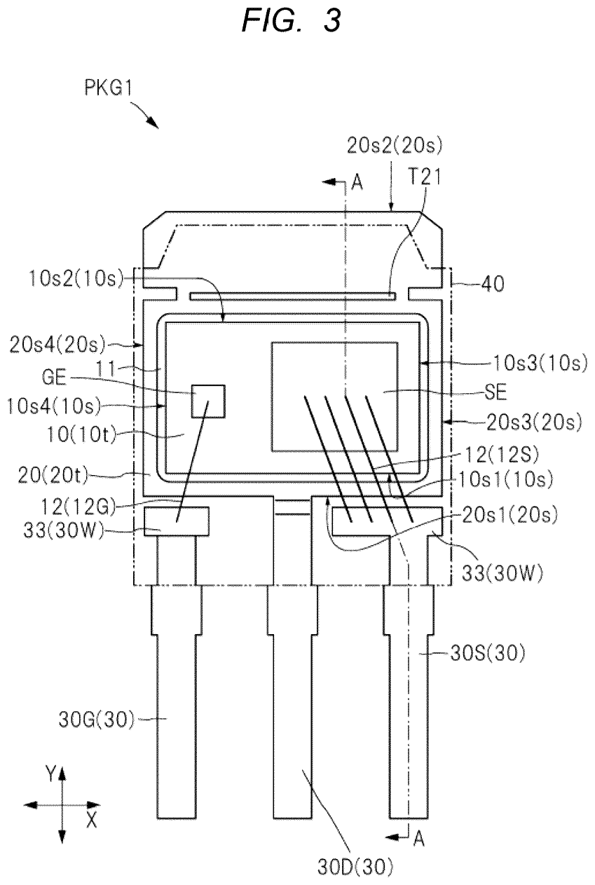

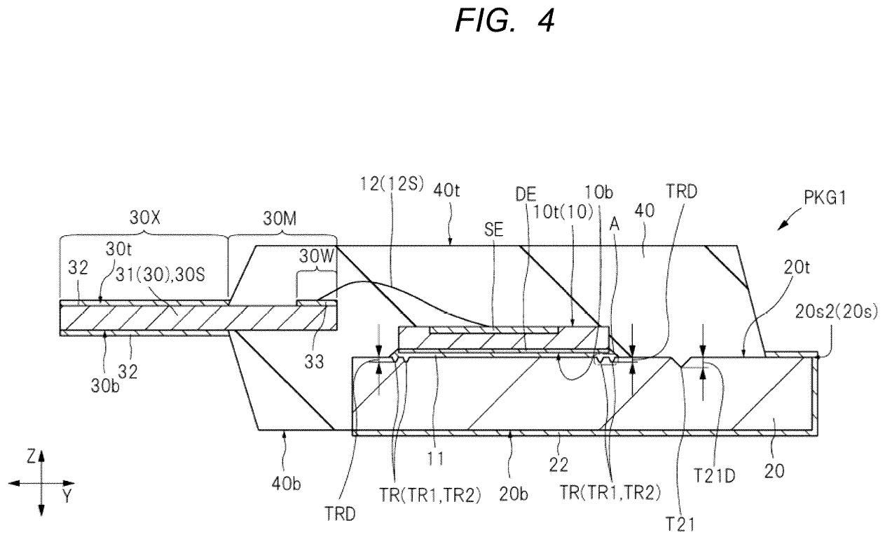

First, a package structure of a semiconductor device PKG1 shown in FIG. 1 will be described. FIG. 1 is an upper surface view of a semiconductor device according to the present embodiment. Also, FIG. 2 is a lower surface view of the semiconductor device shown in FIG. 1. Also, FIG. 3 is a transparent plan view showing an internal structure of the semiconductor device in a state that a sealing body shown in FIG. 1 is removed. Also, FIG. 4 is a cross-sectional view along a line A-A shown in FIG. 3.

FIGS. 1 to 4 describe either the X direction (refer to FIGS. 1 to 3), Y direction, or Z direction (refer to FIG. 4). The Y direction is a side intersecting the X direction, and in the following description, the X and Y directions are orthogonal to each other. The Z direction is orthogonal to both the X and Y directions. In other words, the Z direction is the normal direction to the X-Y plane that includes the X and Y directions. In the following description, “thickness” principally means the length in the Z direction. Also, in the following description, “plan view” principally means the view seen from the X-Y plane.

The semiconductor device PKG1 of the present embodiment includes a semiconductor chip 10 (refer to FIGS. 3 and 4), a die pad (metal plate, chip mounting part, heat dissipation plate) 20 (refer to FIGS. 2 to 4), a plurality of leads (terminals) 30, and a plurality of wires 12 (refer to FIG. 3).

As shown in FIG. 3, the die pad 20 has an upper surface (surface) 20t. The semiconductor chip 10 is mounted on the upper surface 20t of the die pad 20 via a die bond material 11. The plurality of leads 30 is arranged along the side 10s1 of the plurality of sides 10s of the semiconductor chip 10, which extends in the X direction. A plurality of electrode pads (gate electrode pad GE and source electrode pad SE shown in FIG. 3) arranged on the upper surface (chip surface, surface) 10t of the semiconductor chip 10 and the plurality of leads 30 is electrically connected with each other via the plurality of wires. As shown in FIG. 4, the semiconductor chip 10 and the plurality of wires 12 are sealed in a sealing body 40. Moreover, the semiconductor chip 10, the upper surface 20t of the die pad 20, and the inner lead parts (sealed parts) 30M (refer to FIG. 4) of the plurality of leads 30 is sealed by the sealing body 40. The sealing body (resin sealing body, resin, mold resin) 40 is arranged to contact the die pad 20 and the inner lead parts 30M of the leads 30.

As shown in FIG. 4, the semiconductor chip 10 has an upper surface (main surface, front surface, surface) 10t and a lower surface (main surface, rear surface, surface) 10b opposite the upper surface 10t. As shown in FIG. 3, the semiconductor chip 10 has four sides (chip sides) 10s in plan view. The four sides 10s consist of the side 10s1 extending in the X direction, the side 10s2 on the opposite side of side 10s1, the side 10s3 intersecting sides 10s1 and 10s2 and extending in the Y direction, and the side 10s4 on the opposite side of side 10s3. The side 10s1 is the side among the four sides 10s of the semiconductor chip 10 that is positioned closest to each of the plurality of leads 30 and extends in the X direction. In the example shown in FIG. 3, the semiconductor chip 10 forms a rectangle in plan view, with the long sides, sides 10s1 and 10s2, arranged to extend along the X direction.

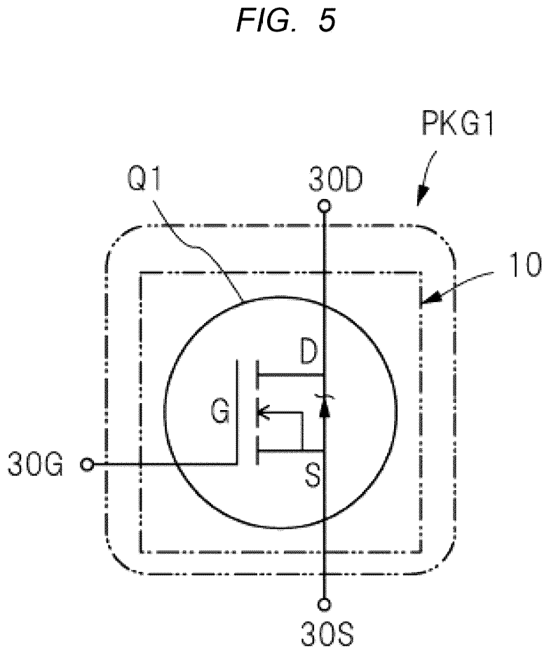

A gate electrode pad GE and a source electrode pad SE are arranged on the upper surface 10t of the semiconductor chip 10. The semiconductor chip 10 has an insulating film (passivation film), which has the plurality of opening portions, on its upper surface 10t. Both the gate electrode pad GE and the source electrode pad SE are exposed from the insulating film at these opening portions. The area of the source electrode pad SE is larger than that of the gate electrode pad GE. The gate electrode pad GE is an electrode pad coupled with the gate electrode G of the transistor Q1, which will be described later in FIG. 5. The source electrode pad SE is an electrode pad coupled with the source S of the transistor Q1 shown in FIG. 5 explained afterward.

As shown in FIG. 4, there is a drain electrode pad (drain electrode) DE on the lower surface 10b of the semiconductor chip 10. This drain electrode pad DE is coupled with the drain D of the transistor Q1, as will be described later in FIG. 5. In the example shown in FIG. 4, the entire lower surface 10b of the semiconductor chip 10 serves as the drain electrode pad DE. In this embodiment, a vertical channel structure MOSFET is exemplified as an example of the transistor Q1. Therefore, the drain electrode pad DE is located on the lower surface 10b of the semiconductor chip 10, which is the opposite side of the surface where the gate electrode pad GE and the source electrode pad SE are placed. Although not shown, as a modified example of this embodiment, if a lateral channel structure MOSFET is used, the gate electrode pad GE, the source electrode pad SE, and the drain electrode pad DE would be arranged on the upper surface 10t of the semiconductor chip 10.

As shown in FIGS. 3 and 4, the semiconductor device PKG1 includes a die pad (metal plate, chip mounting part, heat dissipation plate) 20 on which the semiconductor chip 10 is mounted. Both the die pad 20 and the plurality of leads 30 (see FIG. 3) have a substrate 31 made of, for example, copper (Cu) or an alloy material primarily composed of copper (Cu). As shown in FIG. 4, the die pad 20 has an upper surface (surface, main surface, chip mounting surface) 20t on which the semiconductor chip 10 is mounted via a die bond material 11, and a lower surface (surface, main surface, rear surface, main surface) 20b, which is opposite to the upper surface 20t.

In this embodiment, the die bond material 11, which electrically connects the drain electrode pad DE (see FIG. 4) to the die pad 20, is made of a conductive material. The conductive die bond material 11 can be exemplified by a resin material containing a conductive particle or solder material. The resin material containing a conductive particle is called conductive resin or conductive paste. Those using silver particles are referred to as silver paste.

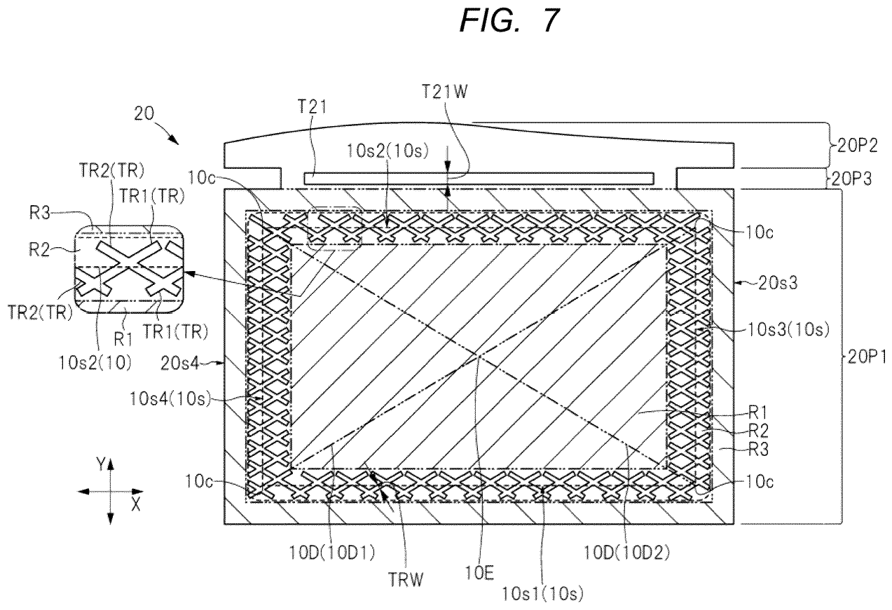

As a modified example of this embodiment, if the element structure without an electrode on the lower surface 10b of the semiconductor chip 10 (for example, a transistor with a lateral channel structure) is applied, it is not essential for the die bond material 11 to be conductive. In this case, a non-conductive adhesive, such as a resin adhesive, can be used. Although not shown, a metal film (not shown) with higher adhesiveness to the die bond material 11 than the copper (Cu) or copper alloy, which is the substrate of the die pad 20, may be arranged on a part of the upper surface 20t of the die pad 20 (for example, the entire or a part of the region R1 shown in FIG. 7). This can improve the adhesive strength between the die bond material 11 and the die pad 20.

Additionally, as shown in FIG. 2, the die pad 20 has four sides 20s in plan view. Specifically, the die pad 20 includes a side 20s1 extending in the X direction, a side 20s2 positioned on the opposite side of side 20s1, a side 20s3 extending in the Y direction and intersecting with side 20s1, and a side 20s4 positioned on the opposite side of side 20s3 and intersecting with side 20s1.

The die pad 20 has a main body portion (section) 20P1 that includes the area where the semiconductor chip 10 (refer to FIG. 3) is mounted, a header part (section) 20P2 that includes the side 20s2 positioned on the opposite side of side 20s1 in plan view, and a connecting part (section) 20P3 that links the main body portion 20P1 and the header portion 20P2. Each of the aforementioned sides 20s1, 20s3, and 20s4 is a side of the main body portion 20P1 of the die pad 20. Moreover, the aforementioned side 20s2 is a side of the header portion 20P2 of the die pad 20.

The main body portion 20P1 is an area that includes the region for mounting the semiconductor chip 10 (refer to FIG. 3) and the region where a fixture is contacted to secure the die pad 20 during the step (the wire bond step mentioned later) of joining wires 12 to the semiconductor chip. The main body portion 20P1 is comprised of a quadrangle in plan view. In the example shown in FIG. 2, the main body portion 20P1 forms a rectangle, with side 20s1 being the longer side. The semiconductor chip 10 is arranged such that its side 10s1 and the side 20s1 of the die pad 20 extend along each other in plan view.

The header portion 20P2 is integrally formed with the main body portion 20P1 and the connecting portion 20P3, but the semiconductor chip 10 is not mounted on the header portion 20P2. The side 20s2 of the header portion 20P2 and its surrounding area are exposed from the sealing body 40. By having the header portion 20P2 and the main body portion 20P1 integrally formed and exposed from the sealing body 40, the heat dissipation characteristics of the semiconductor device PKG1 can be improved.

In other words, the header portion 20P2 functions as a heat dissipation fin for the semiconductor device PKG1.

The connecting portion 20P3 is a section for linking the header portion 20P2 and the main body portion 20P1. As shown in FIG. 2, the width WP3 of the connecting portion is smaller than the width WP1 of the main body portion 20P1. Also, the width WP3 of the connecting part is smaller than the width WP2 of the header portion 20P2. In the example shown in FIG. 2, the widths WP1 and WP2 are of the same length. The term “width WP1” refers to the length from one side 20s3 of the main body portion 20P1 shown in FIG. 2, in the X direction, to the other side 20s4 positioned on the opposite side of this side 20s3. The term “width WP2” refers to the length from one side of the header portion 20P2 shown in FIG. 2, in the X direction, to the other side positioned on the opposite side of this side. Furthermore, the term “width WP3” refers to the length from one side of the connecting portion 20P3 shown in FIG. 2, in the X direction, to the other side positioned on the opposite side of this side. In the case of the die pad 20, because the connecting portion 20P3 with a smaller width WP3 than both widths WP1 and WP2 is positioned between the main body portion 20P1 and the header portion 20P2, the planar shape of the die pad 20 forms a “constricted” shape at the part of the connecting portion 20P3. Additionally, the constricted portion (narrow portion) of the die pad 20 is embedded with the sealing body 40. A die pad 20 is provided with a constricted portion, and by embedding a sealing body in this constricted portion, it is possible to suppress the separation between the sealing body 40 and the die pad 20.

Furthermore, as shown in FIGS. 2 and 4, the lower surface 20b of the die pad 20 is exposed from the sealing body 40. In the example shown in FIG. 2, the area of the lower surface 20b of the die pad 20 is equivalent to or greater than the area of the lower surface 40b of the sealing body 40. By exposing the lower surface 20b of the die pad 20 from the sealing body 40, the heat dissipation characteristics of the die pad 20 can be improved. Also, when the die pad 20 is bonded to a terminal of a mounting substrate (not shown), the die pad 20 itself can be used as a drain terminal (or a collector terminal in the case of an IGBT).

From the perspective of increasing the thermal capacity of the die pad 20, or from the perspective of increasing the cross-sectional area of the conductive path through which current flows, it is preferable for the thickness of the die pad 20 (i.e., the length in the Z-direction) to be thicker. In the example shown in FIG. 4, the thickness of the die pad 20 is greater than the thickness of the semiconductor chip 10. Moreover, the thickness of the die pad 20 (the distance from the upper surface 20t to the lower surface 20b) is greater than the thickness of the lead 30 (the distance from the upper surface 30t to the lower surface 30b). For example, in the example shown in FIG. 4, the thickness of the die pad 20 is about 500 μm to 2000 μm.

Also, a part (outer portion, exposed portion), which is exposed from the sealing body 40, of the die pad 20 is covered with a metal film 22. Similarly, for each of the plurality of leads 30, the part exposed from the sealing body 40 (the outer lead portion 30X) is covered with a metal film 32. This metal film 22 and metal film 32 are metal films intended to improve the wettability of the solder material used as a connecting material when mounting the semiconductor device PKG1 on a mounting substrate. The metal film 22 is, for example, a plating metal film formed by a plating method. On the other hand, the metal film 32 is a metal film formed by a so-called solder dipping method, in which each of the plurality of leads 30 is dipped into molten solder liquid during the manufacturing step of the semiconductor device. As will be described later, in the present embodiment, the metal film 22 is, for example, a plating film containing nickel (Ni), whereas the metal film 32 is a solder film made of solder material containing tin (Sn).

As shown in FIGS. 3 and 4, the semiconductor device PKG1 has the plurality of leads 30 that are electrically connected with the semiconductor chip 10. As shown in FIG. 3, each of the plurality of leads 30 faces the side 20s1 of the die pad 20 in plan view. However, as shown in FIG. 4, the lower surface 30b of the lead 30 is positioned higher than the upper surface 20t of the die pad 20 in the Z-direction. Therefore, in the cross-sectional view shown in FIG. 4, the lead 30 does not face the side 20s1 of the die pad 20. “The plurality of leads 30 and the side 20s1 of the die pad 20 facing each other in plan view” means that the plurality of leads 30 and the side 20s1 of the die pad 20 appear to be facing each other in plan view as shown in FIG. 3. Therefore, as shown in FIG. 4, there are cases where the end face of the lead 30 and the end face of the die pad 20 do not face each other. Although not shown, as a modified example of the present embodiment, the case where the end face of the lead 30 and the end face of the die pad 20 face each other is also included in the state where “plurality of leads 30 and the side 20s1 of the die pad 20 face each other in plan view.”

The plurality of leads 30 includes a source lead (source terminal) 30S, a drain lead (drain terminal) 30D, and a gate lead (gate terminal) 30G. In the example shown in FIG. 3, the plurality of leads 30 is arranged along the X direction. In the example shown in FIG. 3, in the X direction, the leads are arranged in the order of lead 30G, lead 30D, and lead 30S. However, the arrangement order is not limited to the mode shown in FIG. 3; for example, they may be arranged in the order of lead 30G, lead 30S, and lead 30D.

As shown in FIG. 4, each of the plurality of leads 30 includes an inner lead portion 30M sealed in the sealing body 40 and an outer lead portion (outer portion, exposed portion) 30X exposed from the sealing body 40.

As shown in FIG. 3, the die pad 20 is integrally formed with the lead 30D, which is a drain terminal. The lead 30D is an external terminal electrically coupled with the drain D shown in FIG. 5, to be described later. The lead 30D is electrically connected with the drain electrode pad DE (see FIG. 4) of the semiconductor chip 10 via the die pad 20 and the die bond material 11. Also, since lead 30D is connected (linked) to the die pad 20, it functions as a suspension lead supporting the die pad 20 in the manufacturing step of the semiconductor device to be described later.

Also, as shown in FIG. 3, the gate electrode pad GE of the semiconductor chip 10 and the lead 30G are electrically connected via a wire (conductive member, metal wire) 12 (specifically, the gate wire 12G). Similarly, the source electrode pad SE of the semiconductor chip 10 and the lead 30S are electrically connected via wire 12 (specifically, the plurality of source wires 12S). The wire 12 is a conductive member connecting the electrode pads on the upper surface 10t side of the semiconductor chip 10 and the lead 30, and is made mainly of metals such as aluminum (Al), copper (Cu), silver (Ag), or gold (Au).

As shown in FIG. 3, one end of the source wire 12S is bonded to the source electrode pad SE of the semiconductor chip 10. On the other hand, the other end of the wire 125, opposite to the one end, is bonded to the metal film 33 (see FIG. 4) covering the wire bond region 30 W of the lead 305. One end of the gate wire 12G is bonded to the gate electrode pad GE of the semiconductor chip 10. On the other hand, the other end of the wire 12G, opposite to the one end, is bonded to the metal film (not shown) covering the wire bond region 30 W of the lead 30G. The metal film 33 is, for example, a film made of nickel (Ni) or silver (Ag). By bonding the wire 12 to the metal film 33 covering the wire bond region 30 W, the bonding strength between the wire 12 and the lead 30 can be improved. The metal film covering the wire bond region 30 W of the lead 30G is made of the same material as the metal film 33 shown in FIG. 4.

Furthermore, in the power semiconductor device, a current, which is larger than a current flowing through the wiring path connected with the gate electrode pad GE, flows through the wiring path connected with the source electrode pad SE. For this reason, in the example shown in FIG. 3, the plurality of wires 12S is connected with the source electrode pad SE. It should be noted that the shape and number of wires 12 are not limited to the embodiment shown in FIG. 3, and various modifications are possible. For example, the thickness of wire 12S may be thicker than that of wire 12G. Alternatively, a strip-shaped conductive member may be used as wire 125. Examples of strip-shaped conductive members include metal ribbons made of aluminum (Al) and metal plates made of copper (Cu). Also, for example, the number of wires 12G and the number of wires 12S may be the same.

The semiconductor chip 10, the inner lead portions 30M of the plurality of leads 30, and the plurality of wires 12 are sealed with the sealing body 40. The sealing body 40 is a resin body that seals the semiconductor chip 10 and wires 12, having an upper surface 40t (refer to FIGS. 1 and 4) and a lower surface (mounting surface) 40b (refer to FIGS. 2 and 4) located opposite the upper surface 40t. Also, as shown in FIGS. 1 and 2, both the upper surface 40t (refer to FIG. 1) and the lower surface 40b (refer to FIG. 2) of the sealing body 40 have a plurality of sides 40s at their peripheries.

The sealing body 40 is mainly composed of a thermosetting resin such as an epoxy resin. Furthermore, in this embodiment, to improve the characteristics of the sealing body 40 (for example, expansion characteristics due to thermal effects), filler particles such as silica (silicon dioxide; SiO2) particles are mixed into the resin material.

### <Example of Circuit Configuration>

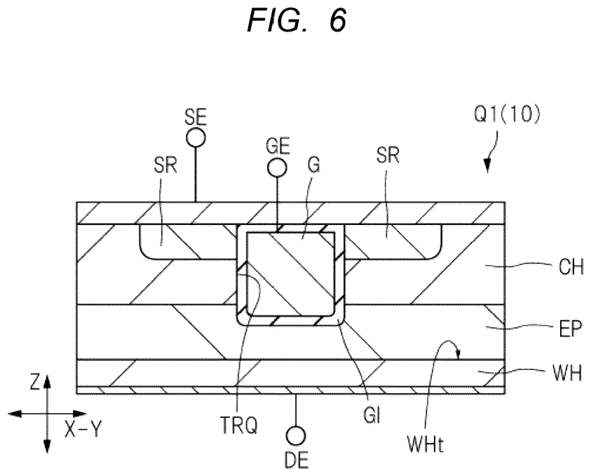

Next, an example of the circuit configuration and transistor element structure provided in the semiconductor device PKG1 shown in FIG. 3 will be described. FIG. 5 is an explanatory diagram schematically showing an example of a circuit provided in the semiconductor device shown in FIG. 1. Also, FIG. 6 is a cross-sectional view of a main portion showing an example of an element structure of a field-effect transistor shown in FIG. 5.

The semiconductor devices used for power control, called power semiconductor devices, have a semiconductor element such as a diode, a thyristor, or a transistor. The transistor is used in various fields, but the transistor that is incorporated into the power control circuit where a large current of 1 A (Ampere) or more flows and operates as switching elements, as in this embodiment, is called a power transistor. The semiconductor device PKG1 of this embodiment has a semiconductor chip 10 having a transistor Q1, which is a power transistor, as shown in FIG. 5. In the example shown in FIGS. 5 and 6, the transistor Q1 provided in the semiconductor chip 10 is a field-effect transistor, specifically, a MOSFET (Metal Oxide Semiconductor Field Effect Transistor). In the power semiconductor device, the transistor is used, for example, as a switching element. The MOSFET used in the power semiconductor device is called a power MOSFET.

The aforementioned MOSFET broadly represents the field-effect transistor structure having a gate electrode made of conductive material placed on a gate insulating film. Therefore, the term “MOSFET” does not exclude a gate insulating film other than an oxide film. Also, the term “MOSFET” does not exclude a gate electrode material other than a metal, such as polysilicon.

The transistor Q1 shown in FIG. 5 is formed by an n-channel type field-effect transistor, for example, as shown in FIG. 6. FIG. 6 is a cross-sectional view of a main part showing an example of an element structure of the field-effect transistor shown in FIG. 5.

In the example shown in FIG. 6, an n-type epitaxial layer EP is formed on the main surface WHt of a semiconductor substrate WH made of, for example, n-type monocrystalline silicon. This semiconductor substrate WH and the epitaxial layer EP constitute the drain region (the region corresponding to the drain D shown in FIG. 5) of the MOSFET. This drain region is electrically connected with the drain electrode pad DE formed on the lower surface 10b (refer to FIG. 4) of the semiconductor chip 10.

On the epitaxial layer EP, a p⁺-type semiconductor region, which is the channel formation region CH, is formed, and on this channel formation region CH, an n⁺-type semiconductor region, which is the source region (the region corresponding to the source S shown in FIG. 5) SR, is formed. The source region SR is electrically connected with the source electrode pad SE formed on the upper surface 10t (refer to FIG. 4) of the semiconductor chip 10 via a lead wiring. Furthermore, a trench (opening portion, groove) TRQ, which penetrates the channel formation region CH from the upper surface of the source region SR and reaches inside the epitaxial layer EP, is formed in the semiconductor regions stacked on the semiconductor substrate WH.

Also, a gate insulating film GI is placed on the inner wall of the trench TRQ. Moreover, a gate electrode G, which is stacked to fill the trench TRQ, is placed on the gate insulating film GI. The gate electrode G is electrically connected with the gate electrode pad GE of the semiconductor chip 10 via a lead wiring.

Additionally, since the transistor Q1 has the drain region and the source region SR arranged in the thickness direction across the channel formation region CH, a channel is formed in the thickness direction (hereinafter referred to as a vertical channel structure). In this case, compared to field-effect transistors where channels are formed along the main surface WHt, the occupied area of the device in plan view can be reduced. Therefore, the planar size of the semiconductor chip 10 can be reduced.

Moreover, in the case of the above-mentioned vertical channel structure, since the channel width per unit area can be increased in plan view, the ON-resistance can be reduced. Note that FIG. 6 shows a diagram of the element structure of the field-effect transistor, and in the semiconductor chip 10 shown in FIG. 5, for example, a plurality (many) of transistors Q1 having the element structure shown in FIG. 6 are connected in parallel. This allows for the construction of a power MOSFET through which a large current exceeding, for example, 1 ampere can flow.

As described above, when constructing a MOSFET by connecting a plurality of transistors Q1 with a vertical channel structure in parallel, the electrical characteristic (mainly, breakdown voltage characteristic, ON-resistance characteristic, and capacitance characteristic) of the MOSFET changes in accordance with the planar size of the semiconductor chip 10. For example, if the planar area of the semiconductor chip 10 is increased, the number of cells (i.e., the number of elements) of the transistors Q1 connected in parallel increases, thus reducing the ON-resistance and increasing the capacitance.

Note that FIGS. 5 and 6 illustrate a MOSFET as an example of the power transistor provided in the power semiconductor device, but various modifications can be applied. For instance, instead of a MOSFET, an Insulated Gate Bipolar Transistor (IGBT) may be provided.

Additionally, while the example shown in FIG. 6 illustratively describes a vertical channel structure transistor, it is possible to replace it with a horizontal channel structure transistor. In this case, the drain electrode pad DE is positioned on the upper surface 10t of the semiconductor chip 10 (refer to FIG. 3). Consequently, the drain electrode pad DE (refer to FIG. 6) of the horizontal channel structure transistor is electrically connected with the drain lead 30D shown in FIG. 3 via an unillustrated wire (drain wire). Furthermore, the area of the drain lead 30D where the drain wire is connected (wire bond area) is covered with a metal film 33, similar to FIG. 4, and the drain wire is connected with the drain lead 30D via the metal film 33.

### <Peeling of Die Pad and Die Bond Material>

Next, the delamination between the die pad 20 and the die bond material 11 will be explained. From the perspective of ensuring the reliability of the semiconductor device PKG1, it is necessary to prevent or suppress the delamination between the die pad 20 and the die bond material 11. Especially in the embodiment like the present one, where the die pad 20 shown in FIG. 4 is electrically connected with the drain electrode pad DE (refer to FIG. 6) of the semiconductor chip 10 via the conductive die bond material 11, suppressing the delamination between the die pad 20 and the die bond material 11 is important in terms of improving the electrical reliability of the semiconductor device PKG1.

However, as shown in FIG. 4, after the semiconductor chip 10 is mounted on the die pad 20, the boundary between the die bond material 11 and the die pad 20 may delaminate. For example, when the semiconductor device PKG1 is powered, the temperature of the semiconductor chip 10 and the members around the semiconductor chip 10 increases due to the heat generation of the semiconductor chip 10. When the power to the semiconductor device PKG1 is turned off, the heat generation of the semiconductor chip 10 stops, and the temperature of the semiconductor chip 10 and the members around the semiconductor chip 10 decreases. At this time, if there is a difference in the coefficient of thermal expansion between the metal (for example, copper or copper alloy) constituting the die pad 20 and the die bond material 11 (for example, solder), stress due to the difference in the coefficient of thermal expansion is applied to the adhesion interface between the die pad 20 and the die bond material 11. The load caused by the repeated temperature rise and fall of the semiconductor device PKG1 is called a temperature cycle load.

In the case of a semiconductor device PKG1 that includes a power transistor, like in this embodiment, the current value flowing through the transistor is high, so the temperature cycle load is particularly large. The stress caused by the temperature cycle load tends to concentrate at positions far from the center of the semiconductor chip, within the adhesion interface between the die pad 20 and the die bond material 11. Also, if there are regions with weak adhesive strength at some parts of the adhesion interface between the die pad 20 and the die bond material 11, stress tends to concentrate at the weak spots. Therefore, a delamination between the die pad 20 and the die bond material 11 is likely to occur near the periphery of the semiconductor chip 10.

Once the delamination occurs, the stress associated with the temperature cycle load applied after the delamination concentrates on the delaminated area. As a result, the delamination between the die pad 20 and the die bond material 11 expands from the initial delamination point to the surroundings, spreading to an extent that affects the electrical reliability of the semiconductor device PKG1.

In the die bond step, where the semiconductor chip 10 is mounted on the die pad 20, the die bond material 11 is applied to a part of the planned overlapping area on the upper surface 20t of the die pad 20, then spread around, or the semiconductor chip 10 is mounted while spreading the die bond material 11 around.

Therefore, to prevent or suppress the delamination between the die pad 20 and the die bond material 11, the following points are important. First, it is important that the die bond material 11 easily spreads around during the die bond step. Second, it is important to improve the adhesive strength between the die pad 20 and the die bond material 11 around the periphery of the semiconductor chip 10.

Based on the above, the inventors of the present invention have conducted studies on techniques that can prevent or suppress the delamination between the die pad 20 and the die bond material 11. The detailed structure of the die pad in this embodiment is described below.

### <Die Pad>

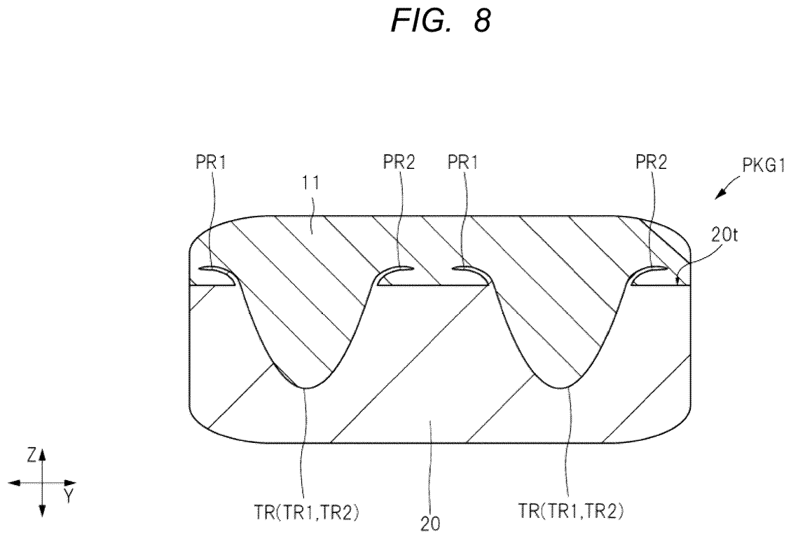

FIG. 7 is an enlarged plan view showing the die pad shown in FIG. 3. In FIG. 7, to illustrate an example of the planar positional relationship between each region of the upper surface 20t of the die pad and the semiconductor chip 10, the outline of the semiconductor chip 10 and the outline of the die bond material 11 are shown in dashed lines. In FIG. 7, the boundary lines of each region of the upper surface 20t of the die pad 20, and the two diagonals of the semiconductor chip 10 are illustrated in chain double-dashed lines. Furthermore, in FIG. 7, regions R1 and R3 are each hatched. FIG. 8 is an enlarged cross-sectional view of a part A shown in FIG. 4.

As shown in FIG. 7, in plan view, the semiconductor chip 10 is comprised of a quadrangle having four sides 10s, four corners 10c where any two of the four sides 10s intersect with each other, and two diagonal lines 10D. Each of the two diagonal lines 10D is a line segment connecting each of the two diagonally located corners 10c out of the four corners 10c. Although it has been described that “the semiconductor chip 10 has two diagonal lines 10D,” this means that two diagonals can be drawn when the plan view of the semiconductor chip is illustrated. Therefore, it is not necessary to visually recognize the diagonal line 10D when actually viewing the semiconductor chip 10. A corner 10c is an intersection where any two of the four sides 10s intersect with each other.

The upper surface 20t of the die pad 20 has a region R1 that includes a point overlapping a center 10E of the semiconductor chip 10, a region R2 that is located around the region R1 and that includes points respectively overlapping the four corners 10c of the semiconductor chip 10, and a region R3 that is located around the region R2. In the example shown in FIG. 7, the region R2 is arranged in annular shape so as to continuously surround the region R1 and includes the points respectively overlapping with four sides 10s of the semiconductor chip 10.

A plurality of grooves TR is formed in the die pad 20 at the region R2 of the upper surface 20t. Each of the plurality of grooves TR terminates at a position not reaching each of the regions R1 and the region R3. In other words, the boundary between the region R1 and the region R2 is located closer to the point overlapping with the center 10E of the semiconductor chip 10 than the position of one end portion of each of the plurality of grooves TR. Also, the boundary between the region R2 and the region R3 is located farther from the point overlapping the center 10E of the semiconductor chip 10 than the position of the other end portion of each of the plurality of grooves TR.

The plurality of grooves TR includes a plurality of grooves TR1 extending in the extending direction of one (in the example shown in FIG. 7, diagonal line 10D1) of the two diagonal lines 10D of the semiconductor chip 10, and a plurality of grooves TR2 extending in the extending direction of the other one (in the example shown in FIG. 7, diagonal line 10D2) of the two diagonal lines 10D.

Each of the plurality of grooves TR1 is arranged so as to intersect with one or more of the plurality of grooves TR2. Each of the four sides 10s of the semiconductor chip 10 overlaps with one or more of the plurality of grooves TR. In the example shown in FIG. 7, each of the four sides 10s of the semiconductor chip 10 overlaps with each of the plurality of grooves TR1 and the plurality of grooves TR2.

As mentioned above, to prevent or suppress the separation between the die pad 20 and the die bond material 11, firstly, it is important that the die bond material 11 can easily spread around during the die bonding step. From this perspective, this embodiment is preferable in the following respects.

Although detailed later, in the die bonding step where the semiconductor chip 10 is mounted on the die pad 20 as shown in FIG. 4, after applying the die bond material 11 in the region R1 as shown in FIG. 7, the step includes expanding the application range of the die bond material 11 towards the periphery of the region R1 by pressing it from above. The member pressing the die bond material 11 may use a dedicated tool for pressing, or the semiconductor chip 10 itself may be used as the pressing member.

In the case of this embodiment, the plurality of grooves TR is arranged in region R2. Therefore, when the applied die bond material 11 reaches the region R2, it gets embedded into the groove TR. The die bond material 11 that has entered the groove TR spreads from the region R2 to the region R3 along the extending direction of the groove TR due to capillary action. The ease of spreading of the die bond material 11 from the region R1 to the region R3 is improved when the groove TR is formed in the region R2 compared to when no grooves TR are formed. Thus, according to this embodiment, since the plurality of grooves TR is formed in the region R2, the die bond material 11 spreads more easily into the region R2 compared to when no grooves TR are formed.

However, although not shown, as an examined example for this embodiment, consider the case where either one of the grooves TR1 and TR2 shown in FIG. 7 is formed alone in region R2. In this examined example, the die bond material 11 may spread locally near the groove TR formed alone. In this case, the planar shape of the die bond material 11 becomes locally protruded, making it prone to stress concentration at the protruded parts.

On the other hand, in the case of this embodiment, as shown in FIG. 7, each of the plurality of grooves TR1 is arranged to intersect with one or more of the plurality of grooves TR2. In the example shown in FIG. 7, each of the plurality of grooves TR1 is arranged to intersect with the plurality of grooves TR2 (two in FIG. 7).

The layout of the plurality of grooves can be expressed as follows, based on the plurality of grooves TR2. Namely, each of the plurality of grooves TR2 is arranged to intersect with one or more of the plurality of grooves TR1. In the example shown in FIG. 7, each of the plurality of grooves TR2 is arranged to intersect with the plurality of grooves TR1 (two in FIG. 7).

In the case of this embodiment, the plurality of grooves TR includes the grooves TR1 and TR2 extending in different directions and intersecting each other. In this case, during the die bonding step, the die bond material 11 that has entered the grooves TR1 or TR2 spreads throughout the plurality of grooves TR1 and TR2, which are intersecting with each other, due to capillary action. Therefore, the planar shape of the die bond material 11 becomes a quadrangle along each side 10s of the semiconductor chip 10, as shown in FIG. 3. In other words, according to this embodiment, the planar shape of the die bond material 11 is less likely to become locally protruded. Therefore, it is less prone to stress concentration at the protruded parts, which suppresses the peeling between the die bond material 11 and the die pad 20.

Moreover, during the die bonding step mentioned above, when spreading the die bond material 11 from region R1 to region R3, it is particularly difficult for the die bond material 11 to spread along the extension line of the diagonal line 10D of the semiconductor chip 10.

In this embodiment, the groove TR1 extends along the direction of diagonal line 10D1, and groove TR2 extends along the direction of diagonal line 10D2. Therefore, in the region R2 shown in FIG. 7, the plurality of grooves TR located near corner 10c include groove TR1 arranged along the extension line of diagonal line 10D1, and groove TR2 arranged along the extension line of diagonal line 10D2. Furthermore, as mentioned above, since the plurality of grooves TR intersects with each other, if the die bond material 11 enters some of the grooves TR, it can spread along the extending direction of the grooves TR. Therefore, in this embodiment, it is possible to spread the die bond material 11 especially along the extension lines of the diagonal line 10D of the semiconductor chip 10, where it is difficult for the die bond material 11 to spread.

To prevent or suppress the peeling between the die pad 20 and the die bond material 11, as mentioned above, secondly, it is important to improve the adhesive strength between the die pad 20 and the die bond material 11 around the periphery of the semiconductor chip 10. From this perspective, this embodiment is preferable in the following respects.

As shown in FIG. 7, region R2 includes a region overlapping the periphery of the semiconductor chip 10. In this embodiment, as mentioned above, since the plurality of grooves TR is formed in region R2, it is possible to increase the area of the intimate interface (in other words, the adhesive interface) between the die pad 20 and the die bond material 11 in region R2. Also, the die bond material 11 embedded in the groove TR functions as an anchor that suppresses the thermal expansion and contraction of the die pad 20 and the die bond material 11 in the direction along the X-Y plane shown in FIG. 7. Therefore, in this embodiment, it is possible to improve the adhesive strength between the die pad 20 and the die bond material 11 in region R2. Region R2 includes the vicinity of the periphery of the semiconductor chip 10. Thus, according to this embodiment, it is possible to improve the adhesive strength between the die pad 20 and the die bond material 11 around the periphery of the semiconductor chip 10. As a result, it is possible to prevent or suppress the peeling between the die pad 20 and the die bond material 11.

As mentioned above, the peeling between the die bond material 11 and the die pad 20 is likely to occur near the periphery of the semiconductor chip 10, in other words, in the region R2 shown in FIG. 7. Region R1 is closer to the center 10E of the semiconductor chip 10 compared to region R2. Therefore, even if a temperature cycle load is applied to the semiconductor device PKG1 (refer to FIG. 4), peeling between the die bond material 11 and the die pad 20 is less likely to occur in region R1.

In this embodiment, the plurality of grooves TR is selectively formed only in region R2, and not formed in regions R1 and R3. In other words, each of the plurality of grooves TR terminates at a position that does not reach regions R1 and R3. When the plurality of grooves TR is formed in the region R2, and no grooves TR are formed in the region R1, the flatness of the region R1 and the flatness of the region R2 can be compared as follows. That is, no grooves TR are formed on the upper surface 20t of the die pad 20 in the region R1. In other words, the flatness of the upper surface 20t of the die pad 20 in the region R1 is higher than that of the region R2.

As shown in FIG. 7, when no grooves TR are formed in the region R1, it is possible to reduce the amount of die bond material 11 used in region R1. Alternatively, by not providing the groove TR in the region R1, which is less likely to experience delamination between the die bond material 11 and the die pad 20, it is possible to prevent voids from remaining within the grooves.

The size of the regions R1 and R2, based on the planar dimensions of the semiconductor chip 10, is preferably as follows. As shown in FIG. 7, when the center of region R1 overlaps with the center 10E of the semiconductor chip 10, the region of region R1 is preferably about 50% to 90% of the area of the semiconductor chip 10 (the area viewed in plan in FIG. 7). The area enclosed by the outer edge of the region R2 (i.e., the total area of the regions R1 and R2) is preferably about 110% to 250% of the area of the semiconductor chip 10 (the area viewed in plan in FIG. 7). From the perspective of the versatility of the lead frame, there is an advantage in that a common die pad 20 can be used for semiconductor chips of different planar sizes by setting a wide range for region R2.

In the example shown in FIG. 7, in addition to the plurality of grooves TR, a groove T21 is formed. Groove T21 is a groove that suppresses delamination between the sealing body 40 and the die pad 20 by increasing the contact area between the sealing body 40 and the die pad 20. The resin component constituting the sealing body 40 is called resin, and grooves like groove T21 may be referred to as resin lock grooves. Groove T21 can be formed, for example, by press molding using a mold in the lead frame preparation step described later. Groove T21 is formed in the connecting portion 20P3. Therefore, if delamination occurs at the contact interface between the die pad 20 and the sealing body 40 in the header portion 20P2 (refer to FIG. 7), the progression of delamination can be stopped by groove T21. Hence, even if delamination occurs in the header portion 20P2, it is unlikely to reach the region R2 of the main body portion 20P1 (refer to FIG. 7).

When forming a groove like groove T21 by a pressing, its width is large, and the groove depth is deep. For example, the groove width T21W of the groove T21 shown in FIG. 7 is about 200 μm to 300 μm. Also, the groove depth T21D of the groove T21 shown in FIG. 4 is, for example, about 200 μm. In the case of the pressing, the surroundings of groove T21 are easily deformed, tending to reduce flatness.

On the other hand, from the perspective of realizing the capillary phenomenon mentioned above, the plurality of grooves TR shown in FIG. 7 is preferably narrower and shallower than groove T21. For example, each of the groove widths TRW of the plurality of grooves TR shown in FIG. 7 is smaller than the groove width T21W, for example, about 10 μm to 80 μm. Also, each of the groove depths TRD of the plurality of grooves TR shown in FIG. 4 is shallower than the groove depth T21D of groove T21, for example, about 5 μm to 30 μm.

In the present embodiment, each of the plurality of grooves TR is formed by irradiating with a laser from the top surface 20t side of the die pad 20. In addition to irradiating with the laser, a method such as etching or pressing can be exemplified for forming the groove TR. The groove TR formed by laser irradiation can be made narrower and the depth more stable compared to a groove formed by other mentioned methods.

When forming the groove TR by laser irradiation in the region R1, burrs (protrusions) as a part of the metal removed by the laser remain on both sides of the groove TR. For this reason, the groove TR formed by the laser has the following structural features. Namely, protruding portions PR1 and PR2 are provided on both sides of each of the plurality of grooves TR. Each of the protruding portions PR1 and PR2 is provided along each of the plurality of grooves TR shown in FIG. 7, namely, provided in the extending direction of each of the plurality of grooves TR shown in FIG. 7.

### <Modified Example of Die Pad>

Next, a modified example of the die pad shown in FIG. 7 will be described.

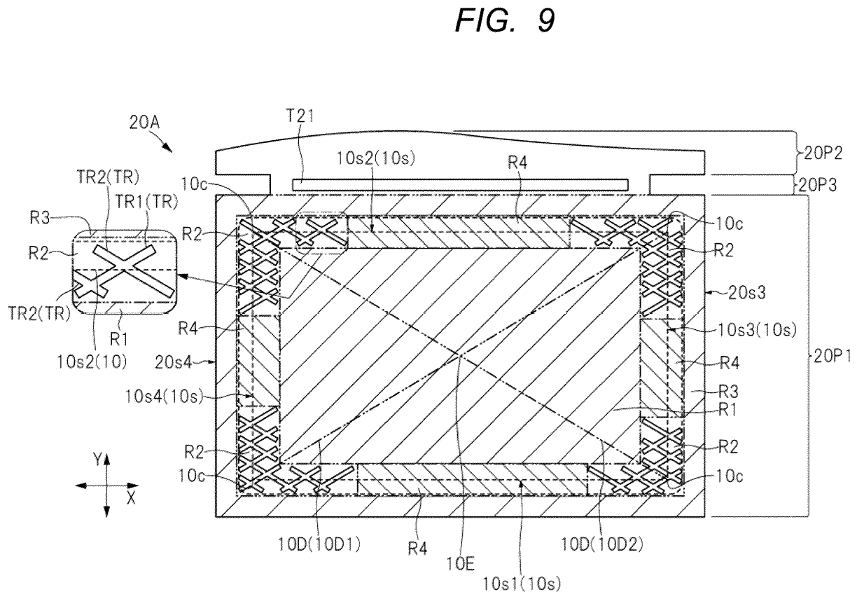

FIG. 9 is an enlarged plan view showing a modified example of the die pad shown in FIG. 7. The die pad 20A shown in FIG. 9 differs from the die pad 20 shown in FIG. 7 in the following points. Namely, the upper surface 20t of the die pad 20A has the plurality (four in FIG. 9) of regions (divided regions) R2 spaced apart from each other. The upper surface 20t of the die pad 20A has a region R4 that is located around the region R1, that is arranged to be adjacent to two, which are adjacent to each other, of the plurality of regions (divided regions) R2, and that includes a point overlapping with any of the four sides 10s of the semiconductor chip 10, and the region R3 that is located around the plurality of regions (divided regions) R2 and the plurality of regions R4. The plurality of grooves TR is not formed in the plurality of regions R4.

The modified example shown in FIG. 9 can also be expressed as follows. The upper surface 20t of the die pad 20A includes a region R1 that contains a point overlapping with the center 10E of the semiconductor chip 10, and the plurality of (four in FIG. 9) regions R2 that is located around the region R1 and contain points overlapping with each of the four corners 10c of the semiconductor chip 10. Each of the plurality of regions R2 includes the plurality of grooves TR, including the grooves TR1 and TR2 described using FIG. 7. Among the plurality of regions R2, region R4 is arranged between regions R2 that are adjacent to each other.

The region R3 is arranged in annular shape so as to surround the plurality of regions R2 and the plurality of regions R4, in plan view. Each of the plurality of grooves TR terminates at a position not reaching the region R1, the region R3 and the region R4. Therefore, the groove TR is not formed in the region R4.

The fact that the groove TR is not formed in the region R4 can be expressed as follows. Namely, the region R4 on the upper surface 20t of the die pad 20A has a higher flatness than region R2.

It was explained that delamination between the die bond material 11 and the die pad 20 is likely to occur near the periphery of the semiconductor chip 10, especially near the corners 10c of the semiconductor chip 10. Each of the four corners 10c is at the longest distance from the center 10E and is subject to the maximum stress.

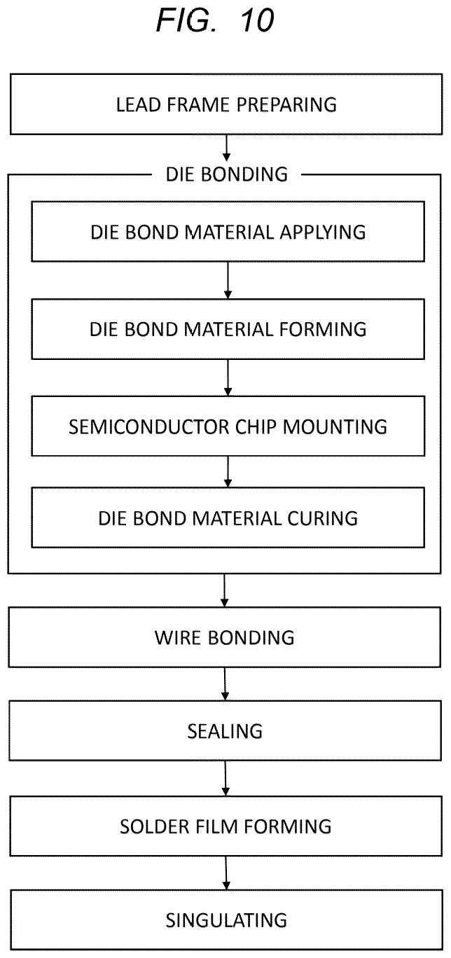

In the case of the modified example shown in FIG. 9, the plurality of grooves TR is selectively formed near the corners 10c, where delamination is particularly likely to occur, in other words, in the regions R2 shown in FIG. 10.

As shown in FIG. 9, when the grooves TR is selectively formed only in the region R2, the die bond material 11 can easily spread along the extending direction of the groove TR at positions overlapping with the corners 10c of the semiconductor chip 10. As a result, delamination between the die pad 20A and the die bond material 11 around the corners 10c can be suppressed. Alternatively, when the groove TR is selectively formed only in the region R2, the amount of die bond material 11 used in the region R4 can be reduced. Alternatively, by not providing the groove TR in the region R4, which is relatively less prone to delamination compared to the region R2, it is possible to prevent voids from remaining in the grooves.

Excluding the differences mentioned above, Die Pad 20A shown in FIG. 9 is similar to Die Pad 20 shown in FIG. 7, hence repetitive descriptions are omitted.

### <Method of Manufacturing Semiconductor Device>

Next, a method of manufacturing the semiconductor device shown in FIGS. 1 to 4 will be described. FIG. 10 is a flowchart showing an example of a manufacturing step for the semiconductor device shown in FIGS. 1 to 4. In the example shown in FIG. 10, the manufacturing method for the semiconductor device of the present embodiment includes a lead frame preparation step, a semiconductor chip mounting step, a wire bonding step, a sealing step, a solder film forming step, and a singulation step.

In the following description, the manufacturing method using Die Pad 20 shown in FIG. 7 will be explained as a representative example. However, as a modified example, the same manufacturing method can be applied when using Die Pad 20A shown in FIG. 9.

### <Lead Frame Preparation Step>

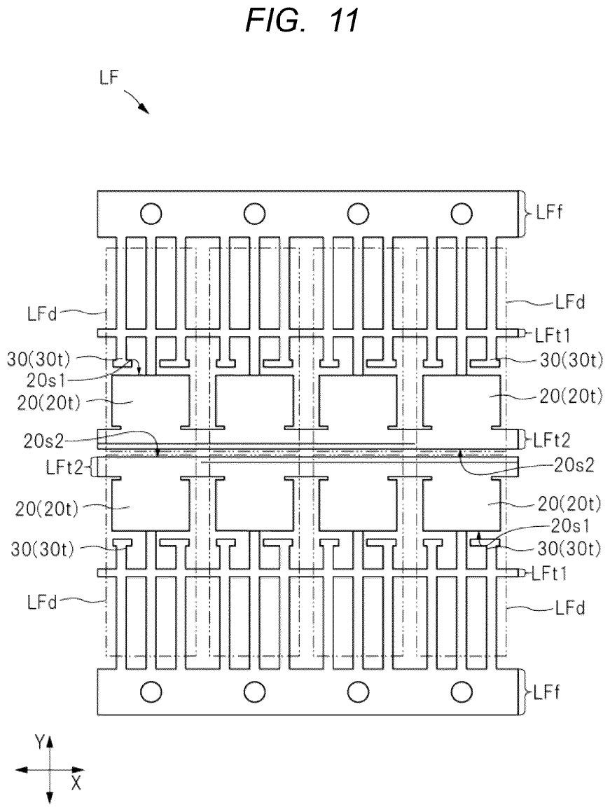

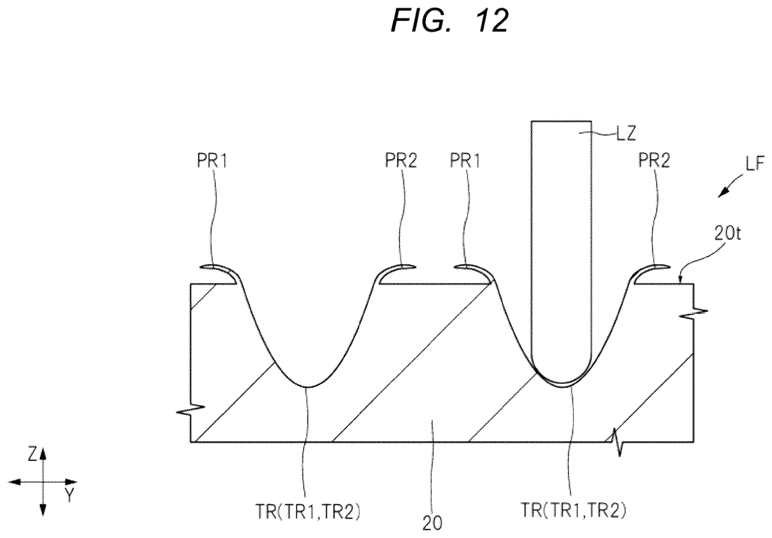

First, in the lead frame preparation step shown in FIG. 10, a lead frame LF as shown in FIG. 11 is prepared. FIG. 11 is an enlarged plan view showing a part of the lead frame prepared in the lead frame preparing step shown in FIG. 10. For details of the structure such as the die pad 20 and the plurality of leads 30 located in the device forming portion LFd shown in FIG. 10, refer to FIGS. 3 through 9 as necessary. FIG. 12 is a cross-sectional view showing a step of forming the groove shown in FIG. 8 by irradiating the die pad with a laser shown in FIG. 11.

As shown in FIG. 11, the lead frame LF prepared in this step includes the plurality of device forming portions LFd connected to the frame portion (frame section) LFf. FIG. 11 shows eight device forming portions LFd. Each of the plurality of device forming portions LFd corresponds to one semiconductor device PKG1 as shown in FIG. 1. The lead frame LF is a so-called multi-piece substrate, where the plurality of device formation parts LFd are arranged in a matrix. By using a lead frame LF equipped with the plurality of device forming portions LFd, it is possible to manufacture the plurality of semiconductor devices PKG1 (refer to FIG. 1) in bulk, thereby improving manufacturing efficiency. In FIG. 11, an example is shown where two rows of the plurality of device forming portions LFd arranged along the X direction are aligned, but there are various modified examples of the arrangement of the device forming portion LFd. For example, a single row or more than three rows may be used.

The lead frame LF is made of a metal material mainly composed of copper (Cu). Each of the plurality of device forming portions LFd is connected to the frame portion LFf. The frame portion LFf serves as a support portion that supports each component formed within each device forming portion LFd until the singulating step shown in FIG. 10.

Also, in the device forming portion LFd, a die pad 20 and the plurality of leads 30 are formed as shown in FIG. 3. The die pad 20 is connected to the frame portion LFf via one of the plurality of leads 30 and is supported by the frame portion LFf. Moreover, each of the plurality of leads 30 is connected to and supported by the frame portion LFf.

Focusing on one of the plurality of device forming portions LFd, this step can be expressed as a die pad preparation step, namely, a step for preparing a die pad with an upper surface 20t.

Furthermore, each of the plurality of leads 30 is connected to each other via a tie bar LFt1. In the example shown in FIG. 11, each of the plurality of die pads 20 is connected to each other via a tie bar LFt2. As shown in FIG. 11, the tie bar LFt2 is located on the opposite side of the plurality of leads 30 via the die pad 20 in the device forming portion LFd, and includes a side 20s2 opposite the side 20s1 facing the plurality of leads 30.

The die pad 20 has grooves T21 formed as shown in FIGS. 7 and 9. The groove T21 is formed by press molding using a mold in the lead frame forming step. Also, the die pad 20 has the plurality of grooves TR formed as shown in FIGS. 7, 8, and 9. Each of the plurality of grooves TR is formed by irradiating the upper surface of the die pad 20 with a laser as described above.

Furthermore, the die pad 20 has the plurality of grooves TR formed as explained using FIGS. 4, 7, 8, and 9. As schematically shown in FIG. 12, each of the plurality of grooves TR is formed by irradiating with the laser LZ toward the upper surface 20t of the die pad 20. In this case, as shown in FIG. 12, the protruding portions PR1 and PR2, which are burrs generated by the laser step, are formed on both sides of the groove TR. As a modified example of this embodiment, there may be cases where the protruding portions PR1 and PR2 are removed.

However, in the case of this embodiment, since the step of removing the protruding portions PR1 and PR2 is not included, as explained using FIG. 8, each of the protruding portions PR1 and PR2 exists in the semiconductor device PKG1, which is the product.

Among the plurality of leads 30, the leads 30 corresponding to the source lead 30S and the gate lead 30G shown in FIG. 3 have a wire bond region 30 W. In the lead frame preparation step, a metal film 33 is formed to cover the upper surface 30t of the wire bond region 30 W. The metal film 33 is made of silver and can be formed, for example, by a plating method.

### <Die Bonding Step>

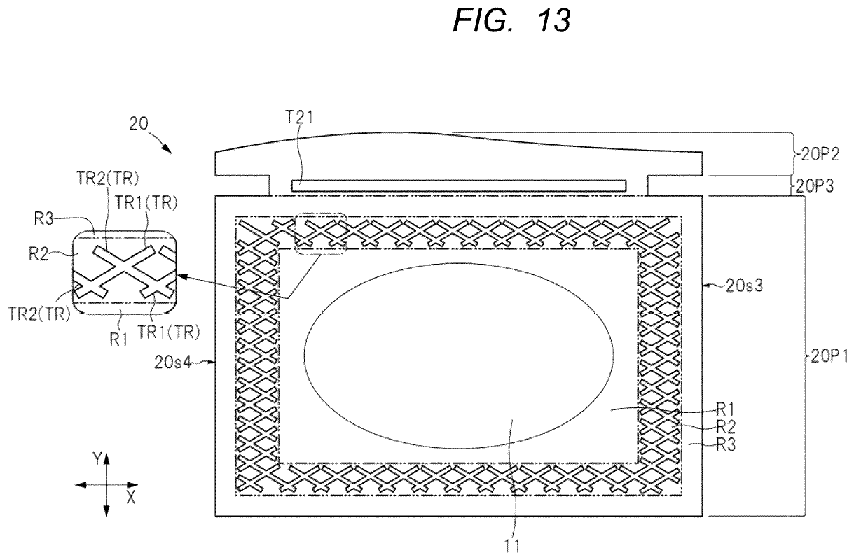

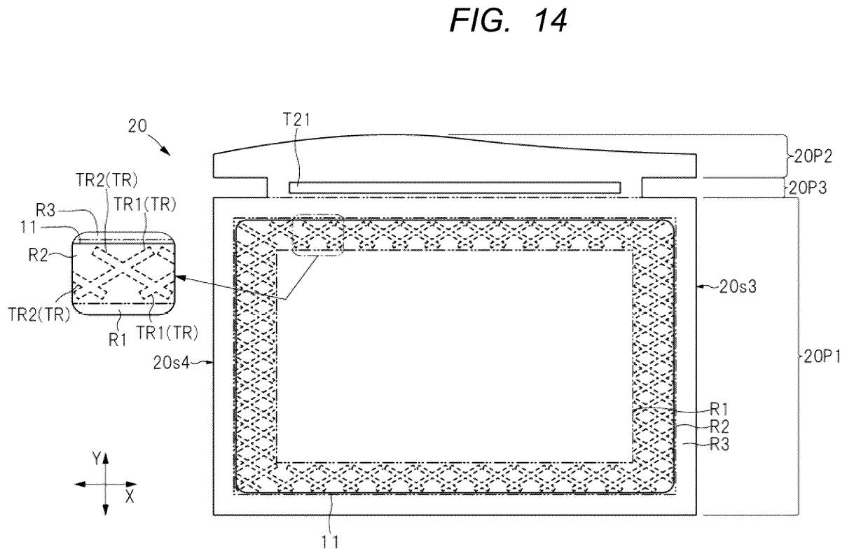

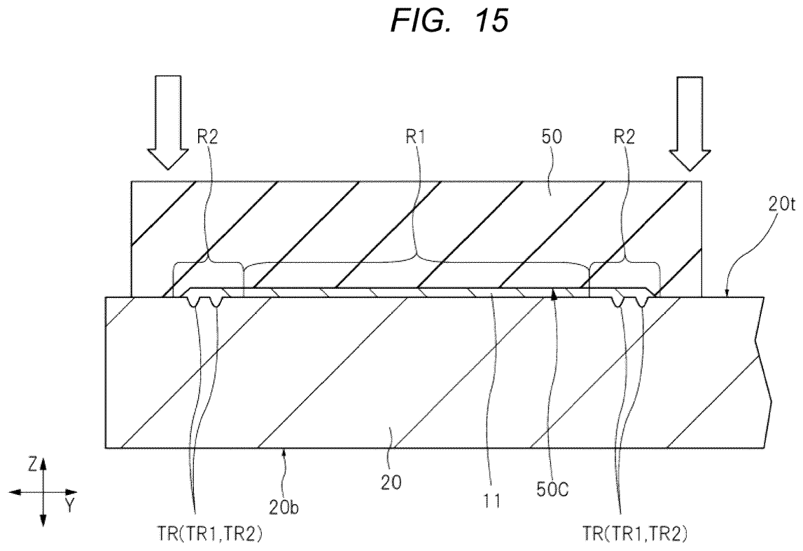

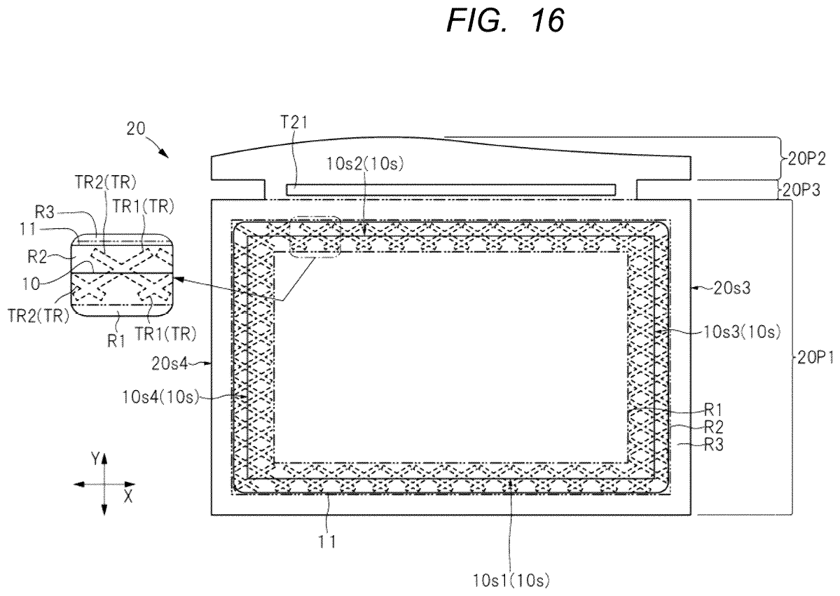

Next, in the die bonding step shown in FIG. 10, as shown in FIG. 3, the semiconductor chip 10 is mounted on the die pad 20. FIG. 13 is an enlarged plan view showing a state where the die bond material is applied onto one of the die pads shown in FIG. 11. FIG. 14 is an enlarged plan view showing a state where the die bond material shown in FIG. 13 is formed (shaped) by pressing it with a molding tool (spanker). FIG. 15 is an enlarged cross-sectional view schematically showing a state where the die bond material shown in FIG. 13 is pressed by the molding tool (spanker). FIG. 16 is an enlarged plan view showing a state where the semiconductor chip is mounted on the die bond material shown in FIG. 14. In each of FIGS. 13, 14, and 16, the outer edge of each of the regions R1, R2, and R3 is illustrated with dashed lines. FIGS. 14 and 16 illustrate the contours of the plurality of grooves TR covered by the die bond material 11 with dotted lines. In FIG. 15, the state where the molding tool 50 is pressing the die bond material 11 from above is schematically indicated using white arrows.

As shown in FIG. 16, in this step, the semiconductor chip 10 is mounted on the upper surface 20t of the die pad 20 via the die bond material 11.

In the case of this embodiment, as shown in FIG. 10, the die bonding step includes a die bond material applying step, a die bond material forming step, a semiconductor chip mounting step, and a die bond material curing step.

In the die bond material applying step shown in FIG. 10, as shown in FIG. 13, the die bond material 11 is applied to region R1 of the die pad 20. The die bond material 11 consists of, for example, a paste material containing solder, flux components, and solvent, and a predetermined amount (volume) of die bond material is applied to region R1 from a dispenser not shown. In this step, the die bond material 11 is applied only to region R1, and not to regions R2 and R3.

As a modified example of this embodiment, the die bond material 11 may be a conductive resin containing conductive particles, such as silver paste. In this case, in this step, a paste-like die bond material 11 containing conductive particles and the resin material containing them is applied to region R1.

Even in the case of this modified example, except for the difference in the material applied, it is similar to this embodiment.

As shown in FIG. 3, the planar shape of the semiconductor chip 10 is, for example, rectangular. As shown in FIG. 13, the shapes of the outer edges of the regions R1 and R2 correspond to the planar shape of the semiconductor chip 10 (refer to FIG. 3), becoming rectangular. As shown in FIG. 13, the shape of the die bond material 11 immediately after being applied in this step is elliptical.

Note that there are numerous modified examples for the shape of the die bond material 11 applied in region R1 in this step. For instance, in the example shown in FIG. 13, a single piece of die bond material 11 formed integrally is arranged to cover the center of region R1. Such an applying method is called a single-point applying method.

However, there are various modified examples of the method of applying die bond material 11. For example, the plurality of pieces of die bond material 11 may be applied at the plurality of locations within region R1 so that they are spaced apart from each other. Such an applying method is called a plurality of applying or multi-point applying method.

Next, in the die bond material forming step shown in FIG. 10, as shown in FIG. 15, the die bond material 11 is formed (shaped, molded) by pressing it from above with a molding tool 50 such that the application range of the die bond material 11 expands toward the periphery of the region R1.

The molding tool 50, known as a spanker, has a cavity 50C on the surface facing the upper surface 20t of the die pad 20. When the molding tool 50 is pressed towards the die pad 20, the paste-like die bond material 11 spreads around within the cavity 50C and reaches region R2. A part of the die bond material 11 that has reached region R2 enters the plurality of grooves TR.

The die bond material 11 that has entered the groove TR progresses along the extending direction of the groove TR due to the capillary action described above. As a result, as shown in FIG. 14, the die bond material 11 is molded to cover the entirety of region R1 and most of region R2.

As explained using FIGS. 7 and 9, each of the plurality of grooves TR is formed in region R2, which overlaps with each corner 10c of the semiconductor chip 10. Therefore, in this step, the die bond material 11 is formed to cover the planned overlapping area with the corners 10c of the semiconductor chip 10. That is, according to the present embodiment and the modified example explained using FIG. 9, in the die bond step, the die bond material 11 easily spreads around, thus suppressing the separation between the die bond material 11 and the die pad 20.

Next, in the semiconductor chip mounting step shown in FIG. 10, as shown in FIG. 16, the semiconductor chip 10 is pressed from above the die bond material 11 applied in the region R1, thereby the die bond material 11 is made to adhere to both the semiconductor chip 10 and the die pad 20, as shown in FIG. 4.

In the case of the present embodiment, the die bond material forming step is performed before the semiconductor chip mounting step. In other words, in the case of the present embodiment, the die bond material 11 applied in region R1 is pre-molded to cover at least a part (preferably all or most) of region R2 before the semiconductor chip 10 is mounted.

Thus, when the die bond material 11 is pre-formed before the semiconductor chip mounting step, in the semiconductor chip mounting step, it is sufficient to press the entire lower surface 10b of the semiconductor chip 10 with a force that ensures it adheres to the die bond material 11.

By the way, as a modified example to the present embodiment, the die bond material forming step explained using FIGS. 14 and 15 may be omitted. In this case, during the semiconductor chip mounting step, the die bond material 11 is molded by pressing it from above with the semiconductor chip 10 such that the application range of the die bond material 11 expands toward the periphery of the region R1.

In this modified example, as shown in FIG. 10, compared to the manufacturing method including the die bond material forming step, it is necessary to press the semiconductor chip 10 to the die bond material 11 with a relatively strong pressing force. Therefore, from the perspective of stabilizing the shape of the die bond material 11 after it has spread to region R2, it is preferable to perform the die bond material forming step in advance using a molding tool as shown in FIG. 15. Alternatively, from the perspective of preventing damage to the semiconductor chip 10 during the semiconductor chip mounting step, it is preferable to perform the die bond material forming step as shown in FIG. 10, where the pressing force applied to the semiconductor chip 10 is relatively low.

Next, in the die bond material curing step shown in FIG. 10, the die bond material 11 shown in FIG. 16 is cured to fix the semiconductor chip 10 onto the die bond material 11.

When the die bond material 11 shown in FIG. 16 is a paste material containing solder, flux components, and solvent, this step involves performing a reflow treatment. Reflow treatment is a step of heating the die bond material 11 until the temperature reaches above the melting point of the solder component, followed by cooling. Through the reflow treatment, the solder component can be bonded to the metal material (in this embodiment, the die pad 20 and the drain electrode pad DE of the semiconductor chip) to which the die bond material 11 is adhered. After the reflow treatment, the solder component hardens as shown in FIG. 4, thus fixing the semiconductor chip 10 onto the die pad 20 via the die bond material 11.

The flux component mentioned above is a surfactant used to improve the interfacial activity of the solder component during the reflow step.

On the other hand, as a modified example of this embodiment, if the die bond material 11 is a conductive resin containing conductive particles, such as silver paste, this step involves performing a cure bake step. The cure bake step is a treatment of heating the die bond material 11 until the temperature reaches above the curing temperature of the thermosetting resin contained in the conductive resin. A cooling step is performed after the cure bake step. By performing the cure bake step, the thermosetting resin component contained in the die bond material 11 hardens, thus hardening the entire die bond material 11. As a result, the semiconductor chip 10 is fixed onto the die pad 20 via the die bond material 11.

### <Wire Bonding Step>

Next, in the wire bonding step shown in FIG. 10, as shown in FIG. 3, the plurality of electrode pads of the semiconductor chip 10 (gate electrode pad GE and source electrode pad SE) is electrically connected with the plurality of leads 30 via the plurality of wires (metal wires) 12.

In this step, the gate electrode pad GE of the semiconductor chip 10 is electrically connected with the lead 30G via the wire 12G. Also, in this step, the source electrode pad SE of the semiconductor chip 10 is electrically connected with the lead 30S via the wire 12S.

Various modifications are applicable to the method of connecting wire 12. Wedge bonding method using a bonding tool called a wedge tool, or ball bonding method where the ball part is bonded to the joined member (electrode pad or lead) using a bonding tool called a capillary, can be exemplified.

In the case of the present embodiment, a metal film 33 made of silver is formed in the wire bond region 30 W (refer to FIG. 4). One end of the wire 12 is bonded to the gate electrode pad GE or source electrode pad SE, and the other end of the wire 12 is bonded to the metal film 33 formed in the wire bond region 30W.

### <Sealing Step>

Next, in the sealing step shown in FIG. 10, the semiconductor chip 10, a part of the die pad 20, a part of each of the plurality of leads 30 (inner lead portion 30M shown in FIG. 4), and the plurality of wires 12 are sealed with an insulating resin, forming the sealing body 40 shown in FIG. 4.

In this step, for example, a molding die including an upper mold (first mold) and a lower mold (second mold) that are unillustrated is used to form the sealing body 40 by the so-called transfer mold method. The die pad 20 and the inner lead parts 30M (refer to FIG. 13) of the plurality of leads 30 of the device forming portions LFd shown in FIG. 11 are positioned within the cavity of the molding die. Then, the lead frame LF is clamped between the upper and lower molds. In this state, when the softened (plasticized) thermosetting resin (insulating resin) is pressed into the cavity of the molding die, the insulating resin is molded following the shape of the cavity.

At this time, a part of the upper surface 20t of the die pad 20 connected to the side 20s2, and the lower surface 20b of the die pad 20 are in close contact with the molding die. Therefore, as shown in FIG. 4, after this step, parts of the upper surface 20t and the lower surface 20b of the die pad 20 are exposed from the sealing body 40.

After the sealing body 40 is formed, it is heated until a part of the thermosetting resin contained in the sealing body 40 hardens (referred to as pre-curing). Once it becomes possible to remove the lead frame LF from the molding die due to this pre-curing, the lead frame LF is removed from the molding die. Then, it is transported to a heating furnace for further heat treatment (cure bake). As a result, the remaining part of the thermosetting resin hardens, thereby the sealing body 40 is obtained.

Moreover, although the sealing body 40 is primarily composed of an insulating resin, by mixing a filler particle, for example, such as a silica (silicon dioxide; SiO2) particle into the thermosetting resin, the functionality of the sealing body 40 (for example, resistance to warping deformation) can be improved.

### <Solder Film Formation Step>

Next, in the solder film formation step shown in FIG. 10, the lead frame LF is immersed in an unillustrated plating solution, and a metal film (metal films 22 and 32 shown in FIG. 4) is formed on the surface of the metal parts (outer part) exposed from the sealing body 40. The metal film 22 formed on the lower surface 20b of the die pad 20 shown in FIG. 4, etc., is pre-formed before this step. As a method for forming the metal film 22, for example, a plating method can be exemplified.

In this step, for example, by the solder dip method, a metal film 32 made of solder (refer to FIG. 4) is formed on the parts of the plurality of leads 30 exposed from the resin (outer lead part). Although not shown, the solder dip method involves placing the lead frame LF shown in FIG. 11 into a solder bath filled with molten solder. At this time, among the lead frame LF, the plurality of leads 30 is selectively immersed in molten solder, and most of the sealing body 40 is not immersed in the molten solder. This allows for the formation of a metal film 32 made of solder (refer to FIG. 4) on each of the plurality of leads 30.

### <Singulation Step>

Next, the singulation step shown in FIG. 10 includes a tie bar cutting step that cuts the tie bar LFt1 shown in FIG. 11, and a lead cutting step that cuts the tip of each of the plurality of leads 30 shown in FIG. 11.

In the tie bar cutting step, the tie bar LFt1 shown in FIG. 11 is cut. Also, in the tie bar cutting step, the tie bar LFt2 is cut, and the plurality of die pads 20 connected via the tie bar LFt2 are divided. After this step, the plurality of leads 30 is connected via the frame portion LFf. Additionally, the plurality of die pads 20 is connected via the drain lead 30D (refer to FIG. 3) functioning as a suspension lead and the frame portion LFf.

A pressing (cutting process) using a punch and die that are not shown can be used in the cutting method for tie bars LFt1 and LFt2. Since this step is performed after the solder film formation step, the newly formed sides by cutting in this step are not covered with the metal film 32.

In the lead cutting step, separating the plurality of leads 30 from the frame portion LFf separates each of the plurality of leads 30. In this step, the tip of each of the plurality of leads 30 is cut using the pressing (cutting process) with a punch and die not shown. The newly formed tip surfaces by cutting in this step are not covered with the metal film 32. Through this step, the device forming portion LFd shown in FIG. 11 is singulated, and the semiconductor device shown in FIG. 1 is obtained.

Through the above steps, the semiconductor device PKG1 shown in FIGS. 1 to 4 is obtained. Then, after necessary electrical tests and visual inspections, the products deemed as good quality are transported to the next step, such as packaging of semiconductor devices.

Although the invention made by the present inventor has been specifically described based on the embodiment, the present invention is not limited to the above embodiment, and it is needless to say that various modifications can be made without departing from the gist thereof.

What is claimed is:

1. A semiconductor device comprising:
a die pad having a first surface;
a semiconductor chip mounted on the first surface of the die pad via a die bond material; and
a sealing body that seals the semiconductor chip, the die bond material, and the first surface of the die pad,
wherein, in a plan view, the semiconductor chip is comprised of a quadrangle having:
four sides;
four corners where any two of the four sides intersect with each other; and
two diagonal lines,
wherein, in plan view, the first surface of the die pad has:
a first region that includes a point overlapping with a center of the semiconductor chip;
a second region that is located around the first region and that includes points overlapping with the four corners, respectively; and
a third region that is located around the second region,
wherein a plurality of grooves is formed in the die pad at the second region,
wherein each of the plurality of grooves terminates at a position not reaching each of the first region and the third region,
wherein the plurality of grooves includes:
a plurality of first grooves each extending in an extending direction of one of the two diagonal lines; and
a plurality of second grooves each extending in an extending direction of another one of the two diagonal lines,
wherein each of the plurality of first grooves is arranged so as to intersect with one or more of the plurality of second grooves, and
wherein each of the four sides of the semiconductor chip overlaps with one or more of the plurality of grooves.

2. The semiconductor device according to claim 1, wherein a flatness of the first region is higher than a flatness of the second region.

3. The semiconductor device according to claim 2, wherein a first protruding portion and a second protruding portion are provided on both sides of each of the plurality of grooves.

4. The semiconductor device according to claim 1,
wherein the second region is arranged in annular shape so as to continuously surround the first region in plan view and includes four points overlapping with the four sides of the semiconductor chip, and
wherein each of the four sides of the semiconductor chip overlaps with each of the plurality of first grooves and the plurality of second grooves.

5. The semiconductor device according to claim 1,
wherein the first surface of the die pad has the second region having a plurality of divided regions spaced apart from each other,
wherein the first surface of the die pad has:
a plurality of fourth regions that is located around the first region, that is arranged to be adjacent to two of the plurality of divided regions and that includes a point overlapping with any of the four sides of the semiconductor chip, and
the third region that is located around the plurality of divided regions and the plurality of fourth regions, and
wherein each of the plurality of grooves terminates at a position not reaching each of the first region, the third region, and the fourth region.

6. The semiconductor device according to claim 5, wherein a flatness of each of the plurality of fourth regions is higher than a flatness of each of the plurality of divided regions.

7. The semiconductor device according to claim 1,
wherein the semiconductor chip has an upper surface, a lower surface opposite the upper surface, a first electrode pad formed on the upper surface, and a second electrode pad formed on the lower surface, and
wherein the second electrode pad of the semiconductor chip is electrically connected with the die pad via the die bond material.

8. A semiconductor device comprising:
(a) preparing a die pad having a first surface;
(b) mounting a semiconductor chip on the first surface of the die pad via a die bond material; and
(c) sealing the semiconductor chip, the die bond material and the first surface of the die pad with a sealing body containing a resin,
wherein, in a plan view, the semiconductor chip mounted on the die pad in (b) is comprised of a quadrangle having:
four sides;
four corners where any two of the four sides intersect with each other; and
two diagonal lines,
wherein, in plan view, the first surface of the die pad prepared in (a) has:
a first region that includes a point overlapping with a center of the semiconductor chip;
a second region that is located around the first region and that includes points overlapping with the four corners, respectively; and
a third region that is located around the second region,
wherein a plurality of grooves is formed in the die pad at the second region by irradiating with a laser,
wherein each of the plurality of grooves terminates at a position not reaching each of the first region and the third region,
wherein the plurality of grooves includes:
a plurality of first grooves each extending in an extending direction of one of the two diagonal lines; and
a plurality of second grooves each extending in an extending direction of another one of the two diagonal lines,
wherein each of the plurality of first grooves is arranged so as to intersect with one or more of the plurality of second grooves,
wherein each of the four sides of the semiconductor chip overlaps with one or more of the plurality of grooves, and wherein the (b) includes:
(b1) applying the die bond material onto the first region of the die pad;
(b2) pressing the die bond material applied in the first region with the semiconductor chip, and making the die bond material adhere to both the semiconductor chip and the die pad; and
(b3) curing the die bond material, and fixing the semiconductor chip onto the die bond material.

9. The method according to claim 8, wherein the (b) further includes:
(b4) after the (b1) and before the (b2), pressing the die bond material from above with a molding tool, thereby molding the die bond material such that the application range of the die bond material expands toward a periphery of the first region.

10. The method according to claim 8, wherein a flatness of the first region is higher than a flatness of the second region.

11. The method according to claim 10, wherein a first protruding portion and a second protruding portion are provided on both sides of each of the plurality of grooves.

12. The method according to claim 10,
wherein the semiconductor chip has an upper surface, a lower surface opposite the upper surface, a first electrode pad formed on the upper surface, and a second electrode pad formed on the lower surface, and
wherein, in the (b), the semiconductor chip is mounted on the first surface of the die pad such that the second electrode pad of the semiconductor chip is electrically connected with the die pad via the die bond material.
